(19) United States
(12) Patent Application Publication
(10) Pub. No.: US 2010/0013009 A1
(43) Pub. Date: Jan. 21, 2010

(54) Structure and Method for Forming Trench Gate Transistors with Low Gate Resistance

(76) Inventor: James Pan, West Jordan, UT (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/333,707

(22) Filed: Dec. 12, 2008

Related U.S. Application Data
(60) Provisional application No. 61/013,985, filed on Dec. 14, 2007.

(51) Int. Cl. H01L 29/78; H01L 21/336

(52) U.S. Cl. 257/330; 438/270; 257/E29.262; 257/E21.41

(57) ABSTRACT

A field effect transistor includes body regions of a first conductivity type over a semiconductor region of a second conductivity type such that the body regions form p-n junctions with the semiconductor region. Trenches extend through the body region and terminate within the semiconductor region. Source regions of the second conductivity type extend over the body regions adjacent the trenches such that the source regions form p-n junctions with the body regions. A gate dielectric layer lines sidewalls of each trench. A metal liner lines the gate dielectric layer in each trench. A gate electrode comprising metallic material is disposed in each trench.

### CROSS-REFERENCES TO RELATED APPLICATIONS

This application claims the benefit of U.S. Provisional Application No. 61/013,985, filed Dec. 14, 2007, which is incorporated herein by reference in its entirety for all purposes.

### BACKGROUND OF THE INVENTION

The present invention relates in general to semiconductor technology and more particularly to trench gate field effect transistors (FETs) with low gate resistance and methods for forming the same.

Generally, an n-channel trench-gate power MOSFET includes an n-type substrate on which an n-type epitaxial layer is formed. The substrate embodies the drain of the MOSFET. A p-type body region extends into the epitaxial layer. Trenches extend through the body region and into the portion of the epitaxial layer bounded by the body region and the substrate (commonly referred to as the drift region). A gate dielectric layer is formed on the sidewalls and bottom of each trench. Source regions flank the trenches. Heavy body regions are formed within the body region between adjacent source regions. Gate electrodes (e.g., from polysilicon) fill the trenches and embody the gate of the MOSFET. A dielectric cap covers the trenches and also partially extends over the source regions. A top-side metal layer electrically contacts the source regions and the heavy body regions. A bottom-side metal layer contacts the substrate.

Improvements in transistor performance as a result of reduced gate resistance in such trench gate transistors and their shielded gate variants are well documented. However, techniques proposed to date for reducing the gate resistance have had limited success. Thus, there is a need for low gate resistance trenched gate transistors and methods for forming the same.

### BRIEF SUMMARY OF THE INVENTION

In accordance with an embodiment of the invention, a field effect transistor includes body regions of a first conductivity type over a semiconductor region of a second conductivity type such that the body regions form p-n junctions with the semiconductor region. Trenches extend through the body region and terminate within the semiconductor region. Source regions of the second conductivity type extend over the body regions adjacent the trenches such that the source regions form p-n junctions with the body regions. A gate dielectric layer lines sidewalls of each trench. A metal liner lines the gate dielectric layer in each trench. A gate electrode comprising metallic material is disposed in each trench.

In one embodiment, contact openings extend into the body regions between adjacent trenches. A heavy body region of the first conductivity type extends in each body region along the bottom of each contact opening. An interconnect layer fills each contact opening and is in direct contact with source regions along sidewalls of the contact openings.

In another embodiment, top surfaces of the source regions are fully covered by a dielectric cap material such that the interconnect layer makes direct contact with the source regions only along sidewalls of the contact openings.

In another embodiment, the gate dielectric layer comprises high-k dielectric.

In another embodiment, each trench further includes a shield electrode disposed below the gate electrode. The gate and shield electrodes are insulated from one another by an inter-electrode dielectric layer.

In another embodiment, each trench further includes a thick bottom dielectric extending along the bottom of the trench below the gate electrode.

In accordance with another embodiment of the invention, a method of forming a field effect transistor includes forming body regions of a first conductivity type in a semiconductor region of a second conductivity type such that the body regions form p-n junctions with the semiconductor region. Trenches extending into the semiconductor region are formed. Source regions of the second conductivity type are formed over the body regions adjacent the trenches such that the source regions form p-n junctions with the body regions. A gate dielectric layer is formed lining sidewalls of each trench. A metal liner is formed lining the gate dielectric layer in each trench. A metallic gate electrode is formed in each trench.

In one embodiment, the method further includes forming contact openings extending into the body regions between adjacent trenches. A heavy body region of the first conductivity type is formed extending in each body region along the bottom of each contact opening. An interconnect layer is formed which fills each contact opening and is in direct contact with source regions along sidewalls of the contact openings.

In another embodiment, a dielectric cap material fully covering top surfaces of the source regions is formed such that the interconnect layer makes direct contact with the source regions only along sidewalls of the contact openings.

In another embodiment, the gate dielectric layer comprises high-k dielectric.

In another embodiment, before forming the gate electrodes: a shield dielectric layer lining lower sidewalls and bottom of each trench is formed; a shield electrode is formed in a lower portion of each trench; and an inter-electrode dielectric layer is formed in each trench over the shield electrode.

In another embodiment, before forming the metallic gate electrode: a polysilicon gate material is formed in each trench; and the polysilicon gate material is removed from each trench.

In another embodiment, the metallic material comprises tungsten.

In another embodiment, the metallic gate electrode is formed after forming the body region.

### BRIEF DESCRIPTION OF THE DRAWINGS

FIGS. 1A-1F are simplified cross-sectional views showing an exemplary method for forming a shielded gate trench MOSFET, according to an embodiment of the present invention;

FIG. 2 is a simplified cross-sectional view showing an exemplary trench gate power MOSFET, according to an embodiment of the present invention; and

FIG. 3 is an exemplary cross-sectional view corresponding to that in FIG. 2, and is provided to show a more accurate representation of the contours of the trench and various other regions, according to an embodiment of the present invention.

### DETAILED DESCRIPTION OF THE INVENTION

In accordance with embodiments of the present invention, techniques directed to integrated circuits and their processing are described. More particularly, in some embodiments, power field effect transistors (FETs) include metallic gate electrodes to advantageously substantially reduce the gate resistance compared to conventional polysilicon gates. A simple process technique is disclosed whereby a polysilicon gate electrode formed in trenches in accordance with conventional techniques is removed and replaced with a metallic gate electrode without using any masking steps. The simple process sequence for removal and replacement of poly gates with metallic gates can easily be integrated with existing processes for forming power MOSFETs without requiring additional masking steps. Merely by way of example, the techniques according to the invention have been applied to trench power MOSFETs, but the invention has a much broader range of applicability. For example, the techniques according to the invention can be applied to trench gate IGBT, and in general to any semiconductor device that may benefit from such techniques. These techniques will be described next.

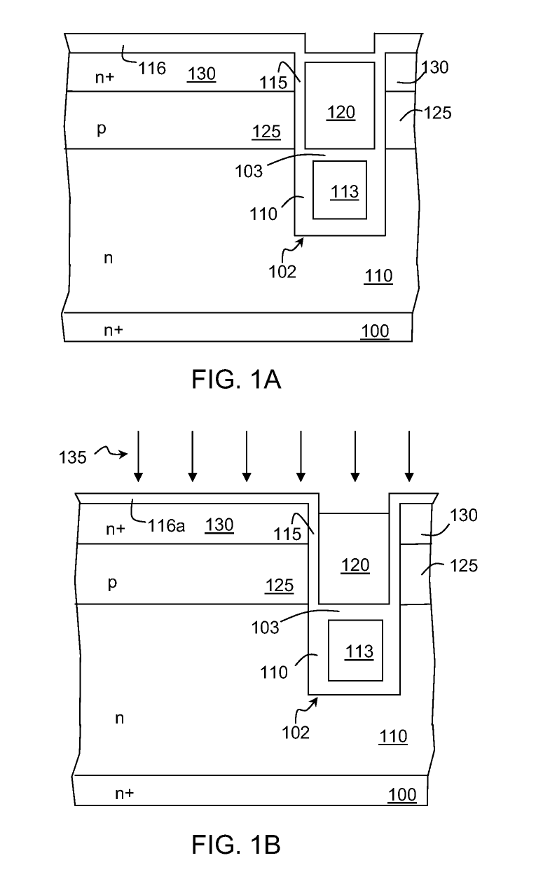

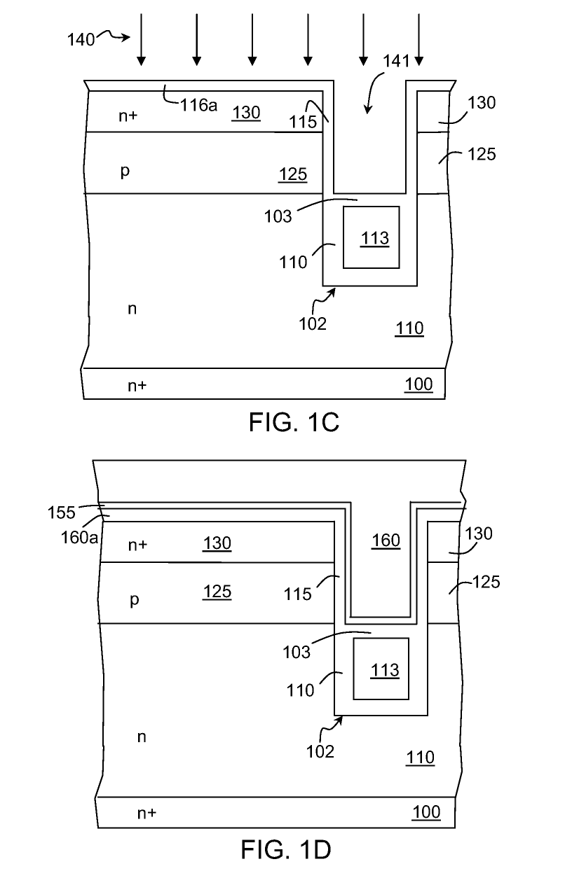

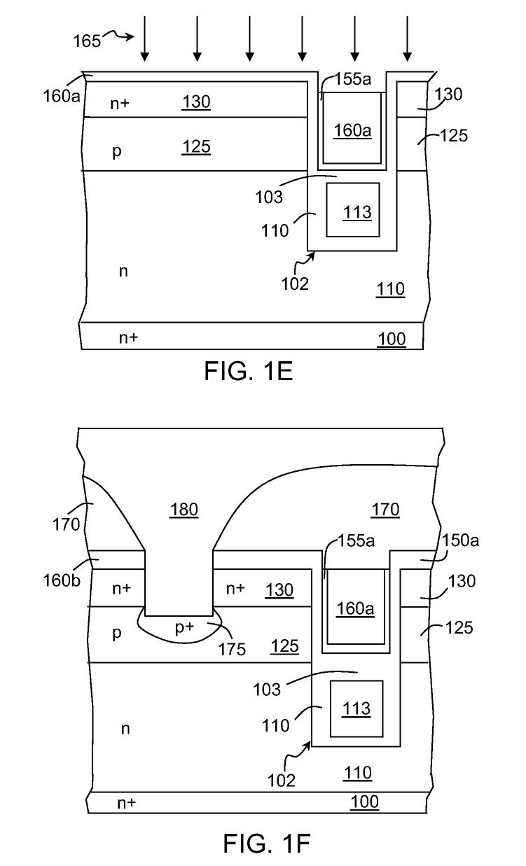

FIGS. 1A-1F are simplified cross-sectional views showing an exemplary method for forming a shielded gate trench MOSFET with a metallic gate according to an embodiment of the present invention. In FIG. 1A, epitaxial layer 110 is formed over substrate 100 using known techniques. Substrate 100 can be a silicon substrate, a III-V compound substrate, a silicon/germanium (SiGe) substrate, an epi-substrate, a silicon-on-insulator (SOI) substrate, a display substrate such as a liquid crystal display (LCD), a plasma display, an electro luminescence (EL) lamp display, or a light emitting diode (LED) substrate, for example. The embodiment shown is an n-channel MOSFET, and substrate 100 and epitaxial layer 110 may include n-type dopants such as phosphorus, arsenic and/or other group V elements.

P-type body region 125 may be formed in or over epitaxial layer 110. In some embodiments, body region 125 may be formed by implanting dopants in epitaxial layer 110. In other embodiments, body region 125 may be formed by an epitaxial process over epitaxial layer 110. Trench 102 extending through body region 125 and terminating within a region of epitaxial layer 110 bounded by body region 125 and substrate 100 is formed using conventional techniques. The region of epitaxial layer 110 bounded by body region 125 and substrate 100 is commonly referred to as the drift region. Shield dielectric layer 101 lining the bottom and lower sidewalls of trench 102 is formed using conventional processes. Shield electrode 113 (e.g., comprising doped or undoped polysilicon) is formed in a bottom portion of trench 102 using known techniques.

Inter-electrode dielectric 103 (e.g., comprising oxide) extending over shield electrode 113 is formed in trench 102 using conventional techniques. Gate dielectric layer 115 (e.g., comprising oxide) lining upper trench sidewalls is formed in accordance with known techniques. In some embodiments, gate dielectric layer 115 is thinner than shield dielectric layer 101. Gate electrode 120 (e.g., comprising doped or undoped polysilicon) is formed in an upper portion of trench 102 using conventional methods. N-type source regions 130 are formed in body regions 125 adjacent trench 102, using known techniques. In some embodiments, body region 125 may be formed before forming trench 102. Alternatively, body region 125 and source regions 130 may be formed after forming trench 102 and the various regions and layers therein. Dielectric layer 116 extending over source regions 130 may be formed at the same time gate dielectric 115 is formed. A thinner dielectric layer extends over gate electrode 120.

While the FIGS. 1A-1F show only one trench 102 and the structure appears asymmetric, it is to be understood that the design to which the cross section views shown and described herein correspond is a cell-based design where one cell is repeated many times to form the complete device.

In FIG. 1B, a removing process 135 completely removes the dielectric layer from over gate electrode 120. Removing process 135 may include a dry etch process and/or a wet etch process. In some embodiments, the dielectric layer on gate electrode 120 is an oxide layer and removing process 135 is a wet etch process using a hydrogen fluoride (HF) solution. Removing process 135 may also remove a portion of dielectric layer 116 over source regions 130. However, dielectric layer 116 is thicker than that over gate electrode 120 so that a portion 116a of dielectric layer 116 remaining after removing process 135 is completed still covers source regions 130. No mask is used in removing process 135.

In FIG. 1C, removing process 140 substantially removes the gate electrode. In some embodiments, removing process 140 may include a dry etch and/or a wet etch. Where gate electrode 120 comprises polysilicon, removing process 140 may use a hydrogen bromide (HBr) solution to remove poly gate 120. Removing process 140 may be a selective etch process whereby poly gate electrode 120 is completely removed without impacting dielectric layers 115 and 116a.

In FIG. 1D, a metal liner 155 lining gate dielectric 115, inter-electrode dielectric layer 103, and dielectric layer 116a is formed. Metal liner 155 advantageously prevents metallic ions from diffusing into the gate dielectric layer. Metal liner 155 may be formed by, for example, a CVD process, a PVD process, other thin film process or various combinations thereof. Liner 155 may include, for example, a titanium (Ti) layer, a titanium nitride (TiN) layer, a tantalum (Ta) layer, a tantalum nitride (TaN) layer, or other material that interfaces properly with gate dielectric 115. In one embodiment, before forming metal liner 155, a thermal process is performed to improve the quality of gate dielectric 115. For example, a high temperature treatment in an oxygen environment can be used. Alternatively, a second dielectric layer suitable for interfacing with metal liner 155 may be formed over gate dielectric layer 115. In yet another embodiment, prior to forming liner 155, gate dielectric 115 (typically comprising oxide) is completely removed and a high-k dielectric layer is formed in its place.

Use of high-k dielectric as gate dielectric 115 may be advantageous in a number of respects. First, a metallic gate is more compatible with high-k dielectric than oxide. Second, high-k dielectric enables using a thinner gate dielectric which lowers the transistor threshold voltage resulting in improved Rdson. The high-k dielectric can be one or more of aluminum oxide (Al₂O₃), hafnium oxide (HfO₂), hafnium oxynitride (HfON), hafnium silicate (HfSiO₄), zirconium oxide (ZrO₂), zirconium oxynitride (ZrON), zirconium silicate (ZrSiO₄), yttrium oxide (Y₂O₃), lanthanum oxide (La₂O₃), cerium oxide (CeO₂), titanium oxide (TiO₂), tantalum oxide (Ta₂O₅), or any combination thereof The high-k dielectric layer may be formed by, for example, a chemical vapor deposition (CVD) process, a physical vapor deposition (PVD) process, or other known processes for forming a high-k material layer.

In FIG. 1D, a metallic fill material 160 is then formed to fill trench 102. Metallic fill material 160 may comprise, for example, Ru, Ti, Ta, W, Hf. Cu, Al; metal nitride stacked gates; metal oxide gates such as RuO₂ or IrO₂; metal nitride gates such as MoN, WN, TiN, TaN, TaAlN; gate silicide such as CoSi₂ or NiSi; or various combinations thereof. In some embodiments, metallic layer 160 may be formed by a CVD process, a PVD process, an electrochemical plating process, an electroless plating process or various combinations thereof.

In FIG. 1E, a removing process 165 is used to recess metallic fill material 160 an metal liner 155 in trench 102. A metallic gate electrode 160a, replacing poly gate electrode 120, is thus formed. In some embodiments, removing process 165 may include a dry etch (e.g., an etch back process), a wet etch, a damascene chemical-mechanical planarization (CMP) process or various combinations thereof Note that none of the processes carried out in replacing poly gate electrode 120 with metallic gate electrode 160a requires a masking step.

In FIG. 1F, dielectric cap layer 170 is formed over metallic gate electrode 160a and source region 130. Cap layer 170 may be an oxide layer, a nitride layer, an oxynitride layer, other dielectric layer or various combinations thereof. In some embodiments, cap layer 170 may be a boron-phosphorus-silicate-glass (BPSG) layer. A contact opening extending into body region 125 is formed using conventional process techniques. A conventional heavy body implant is then carried out to form p+heavy body region 175 in body region 125 along the bottom of the contact opening. Top-side source interconnect 180 is formed to fill the contact opening. Source interconnect 180 makes electrical contact with heavy body region 175 along the bottom of the contact opening, and makes electrical contact with source regions 130 along sidewalls of the contact opening. Cap layer 170 insulates metallic gate electrode 160a from top-side source interconnect layer 180.

Source interconnect layer 180 may comprise, for example, tungsten, copper, aluminum, titanium, tantalum, platinum, cobalt, silicide, or other conductive material. Interconnect layer 180 may be formed by, for example, a CVD process, a PVD process, an electrochemical plating process and/or an electroless plating process. A backside drain interconnect layer (not shown) may be formed to make electrical contact along the backside of substrate 100. The drain interconnect layer may comprise similar material as source interconnect layer 180 and may be formed using the same techniques used for forming source interconnect layer 180.

Thus, by replacing the poly gate with metallic gate as described above, the resistance of the gate electrode is substantially reduce. According to embodiments of the present invention, metallic transistor gate 160a may provide a desired gate resistance because its resistance is lower than that of polysilicon. Also, in the embodiment where high-k dielectric layer is used as gate dielectric 115, due to its high dielectric constant, the high-k dielectric layer can be formed to be physically thinner than conventional gate oxide but have an effective oxide thickness (EOT) similar to conventional gate oxide layers.

Because conventional gate poly is typically formed after the body implant and drive-in, the metallic gate replacing the gate poly is advantageously not subjected to the high-temperature thermal process associated with forming the body region. In addition, the concern that metallic ions of the metallic gate electrode may outgas and contaminate furnaces for performing the thermal process may also be desirably avoided.

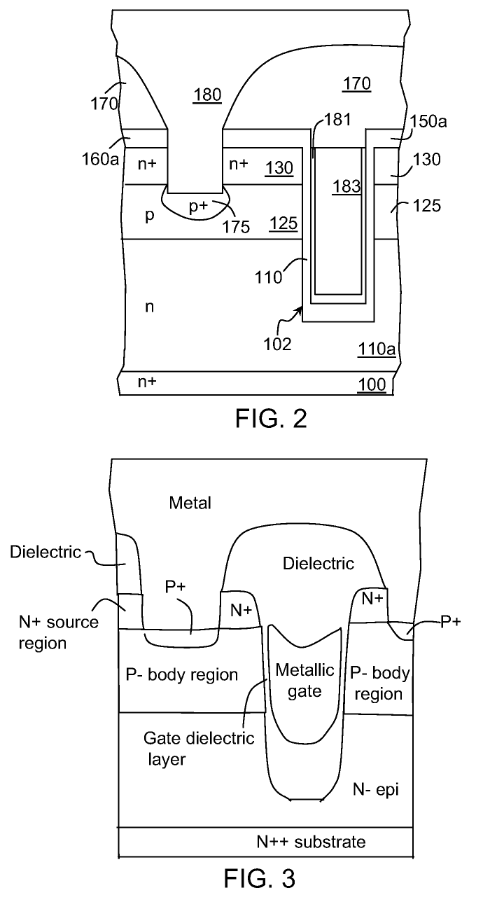

FIG. 2 is a simplified cross-sectional view of an exemplary trench gate MOSFET according to another embodiment of the present invention. This embodiment is substantially similar to the embodiment shown in FIG. 1F except that no shield electrode is formed under gate electrode 183. Instead a dielectric layer which in some embodiments is thicker than the gate dielectric (i.e., what is commonly knows as thick bottom dielectric TBO) extends under gate electrode 183 along the trench bottoms.

FIG. 3 is an exemplary cross-sectional view corresponding to that in FIG. 2, and is provided to show a more accurate representation of the contours of the trench and various other regions.

The techniques in accordance with the invention describe herein are not limited to any particular types of transistors and may be implemented in a variety of devices. For example, the process sequence depicted in FIGS. 1A-1F can be used to form: p-channel shielded gate trench gate MOSFETs (i.e., a transistor similar in structure to that in FIG. 1F except that the conductivity type of all silicon regions is reversed); n-channel shielded gate trench IGBT (i.e., a transistor similar in structure to that in FIG. 1F except that a p-type substrate is used instead of the n-type substrate); p-channel shielded gate IGBT (i.e., a transistor similar in structure to that in FIG. 1F but with silicon regions of opposite conductivity except the substrate is kept n-type); p-channel variation of the trench gate MOSFET in FIG. 2; p-channel and n-channel IGBT variations of the trench gate MOSFET in FIG. 2; trench gate synchronous FET (i.e., integrated trench gate or shielded gate MOSFET and Schottky rectifier); trench gate and shielded gate variety of laterally conducting MOSFETs (i.e., a transistor where the drain contact is made no the top-side) and suprejunction variations of all the above devices (i.e., devices with columns of alternating conductivity type silicon).

Thus, while the above is a complete description of specific embodiments of the present invention, various modifications, variations, and alternatives may be employed. The scope of this invention should thus not be limited to the embodiments described herein, but is instead defined by the following claims.

What is claimed is:

1. A field effect transistor (FET), comprising:
body regions of a first conductivity type over a semiconductor region of a second conductivity type, the body regions forming p-n junctions with the semiconductor region;
trenches extending through the body region and terminating within the semiconductor region;
source regions of the second conductivity type over the body regions adjacent the trenches, the source regions forming p-n junctions with the body regions;
a gate dielectric layer lining sidewalls of each trench;
a metal liner lining the gate dielectric layer in each trench; and
a gate electrode comprising metallic material disposed in each trench.

2. The FET of claim 1 further comprising:
contact openings extending into the body regions between adjacent trenches;
a heavy body region of the first conductivity type extending in each body region along the bottom of each contact opening; and
an interconnect layer filling each contact opening and being in direct contact with source regions along sidewalls of the contact openings.

3. The FET of claim 2, wherein top surfaces of the source regions are fully covered by a dielectric cap material such that the interconnect layer makes direct contact with the source regions only along sidewalls of the contact openings.

4. The FET of claim 1, wherein the gate dielectric layer comprises high-k dielectric.

5. The FET of claim 1, wherein each trench further includes a shield electrode disposed below the gate electrode, the gate and shield electrodes being insulated from one another by an inter-electrode dielectric layer.

6. The FET of claim 1, wherein each trench further includes a thick bottom dielectric extending along the bottom of the trench below the gate electrode.

7. A method of forming a field effect transistor (FET), comprising:
forming body regions of a first conductivity type in a semiconductor region of a second conductivity type, the body regions forming p-n junctions with the semiconductor region;
forming trenches extending into the semiconductor region;
forming source regions of the second conductivity type over the body regions adjacent the trenches, the source regions forming p-n junctions with the body regions;
forming a gate dielectric layer lining sidewalls of each trench;
forming a metal liner lining the gate dielectric layer in each trench; and
forming a metallic gate electrode in each trench, the metallic gate electrode comprising metallic material.

8. The method of claim 7 further comprising:
forming contact openings extending into the body regions between adjacent trenches;
forming a heavy body region of the first conductivity type extending in each body region along the bottom of each contact opening; and
forming an interconnect layer filling each contact opening and being in direct contact with source regions along sidewalls of the contact openings.

9. The method of claim 8 further comprising:
forming a dielectric cap material fully covering top surfaces of the source regions such that the interconnect layer makes direct contact with the source regions only along sidewalls of the contact openings.

10. The method of claim 7, wherein the gate dielectric layer comprises high-k dielectric.

11. The method of claim 7 further comprising:
before forming the gate electrodes:
forming a shield dielectric layer lining lower sidewalls and bottom of each trench;
forming a shield electrode in a lower portion of each trench; and
forming an inter-electrode dielectric layer in each trench over the shield electrode.

12. The method of claim 7 further comprising:
before forming the metallic gate electrode:
forming a polysilicon gate material in each trench; and
removing the polysilicon gate material from each trench.

13. The method of claim 7, wherein the metallic material comprises tungsten.

14. The method of claim 7, wherein the metallic gate electrode is formed after forming the body region.
